(19) United States
(12) Patent Application Publication
(10) Pub. No.: US 2026/0267428 A1
(43) Pub. Date: Sep. 10, 2026

(54) METHOD FOR MANUFACTURING TOUCH SENSOR, METHOD FOR MANUFACTURING DISPLAY DEVICE, TOUCH SENSOR, AND DISPLAY DEVICE

(71) Applicant: Sharp Display Technology Corporation, Kameyama City, Mie (JP)

(72) Inventors: Tetsunori TANAKA, Kameyama City, Mie (JP); Seiji KANEKO, Kameyama City, Mie (JP); Tetsuo FUJITA, Kameyama City, Mie (JP)

(21) Appl. No.: 19/123,967

(22) PCT Filed: Oct. 31, 2022
(86) PCT No.: PCT/JP2022/040621

§ 371 Date: Apr. 24, 2025

(51) Int. Cl. G06F 3/041; G06F 3/044; H10K 59/12; H10K 59/40

(52) U.S. Cl. CPC G06F 3/0412; G06F 3/0446; G06F 2203/04103; G06F 2203/04111; H10K 59/1201; H10K 59/40

(57) ABSTRACT

A method for manufacturing a touch sensor according to the present disclosure includes: a step of forming a first wire having a first side face; a step of forming an intermediate coat layer covering the first wire and having a second side face corresponding to the first side face; a step of forming a second wire; and a step of forming an overcoat layer covering the second wire and having a first opening crossing the second side face in a plan view.

### TECHNICAL FIELD

The present disclosure relates to a method for manufacturing a touch sensor, a method for manufacturing a display device, a touch sensor, and a display device.

### BACKGROUND ART

Patent Document 1 relates to an organic electroluminescence device having a built-in touch sensor. The touch-sensor built-in organic electroluminescent device according to Patent Document 1 includes: a first sealing film; a first detecting electrode; a second sealing film; and a second detecting electrode in the stated order from below.

### CITATION LIST

### Patent Literature

[Patent Document 1] Japanese Unexamined Patent Application Publication No. 2015-050245 (Published on Mar. 16, 2015)

### SUMMARY

### Technical Problem

For touch sensors, there is a need to reduce electrical short-circuit between electrodes. Specifically, as to the technique disclosed in Patent Document 1, a conductor found in the same layer as a plurality of the second detecting electrodes could inadvertently short-circuit the plurality of second detecting electrodes themselves.

### Solution to Problem

A method for manufacturing a touch sensor according to an aspect of the present disclosure includes: a step of forming a first wire above a substrate, the first wire having a first side face; a step of forming an intermediate coat layer covering the first wire and having a second side face corresponding to the first side face; a step of forming a second wire, the second wire being formed of an upper conductive layer covering the intermediate coat layer, and the upper conductive layer being etched to form the second wire; and a step of forming an overcoat layer covering the second wire and having a first opening crossing the second side face in a plan view observed from a direction perpendicular to the substrate.

A touch sensor according to an aspect of the present disclosure includes: a first wire positioned above a substrate and having a first side face; an intermediate coat layer covering the first wire and having a second side face corresponding to the first side face; a second wire positioned above the intermediate coat layer; and an overcoat layer covering the second wire and having a first opening crossing the second side face in a plan view observed from a direction perpendicular to the substrate.

### Advantageous Effect of Disclosure

An aspect of the present disclosure can reduce electrical short-circuit between the electrodes of a touch sensor.

### BRIEF DESCRIPTION OF DRAWINGS

FIG. 1 is a flowchart showing an example of a method for manufacturing a touch sensor according to an embodiment of the present disclosure.

FIG. 2 illustrates cross-sectional views showing an example of the method for manufacturing the touch sensor according to an embodiment of the present disclosure.

FIG. 3 is a plan view showing an example of the method for manufacturing the touch sensor according to an embodiment of the present disclosure.

FIG. 4 illustrates cross-sectional views showing an example of the method for manufacturing the touch sensor according to an embodiment of the present disclosure.

FIG. 5 is a plan view showing an example of the method for manufacturing the touch sensor according to an embodiment of the present disclosure.

FIG. 6 is a cross-sectional view showing a modification of the method for manufacturing the touch sensor according to this embodiment.

FIG. 7 is a plan view showing a modification of the method for manufacturing the touch sensor according to this embodiment.

FIG. 8 is a cross-sectional view showing a modification of the method for manufacturing the touch sensor according to this embodiment.

FIG. 9 is a plan view showing a modification of the method for manufacturing the touch sensor according to this embodiment.

FIG. 10 is a cross-sectional view showing a modification of the method for manufacturing the touch sensor according to this embodiment.

FIG. 11 is a plan view showing a modification of the method for manufacturing the touch sensor according to this embodiment.

FIG. 12 is a plan view showing an example of a wiring pattern of a touch sensor according to an embodiment of the present disclosure.

FIG. 13 is a plan view showing an example of a wiring pattern of the touch sensor according to an embodiment of the present disclosure.

FIG. 14 is a flowchart showing an example of a method for manufacturing a touch sensor according to an embodiment of the present disclosure.

FIG. 15 illustrates cross-sectional views showing an example of the method for manufacturing the touch sensor according to an embodiment of the present disclosure.

FIG. 16 is a flowchart showing an example of a method for manufacturing a display device according to an embodiment of the present disclosure.

FIG. 17 is a cross-sectional view showing an example of the display device according to an embodiment of the present disclosure.

### DESCRIPTION OF EMBODIMENTS

### First Embodiment

### Method for Manufacturing Touch Sensor

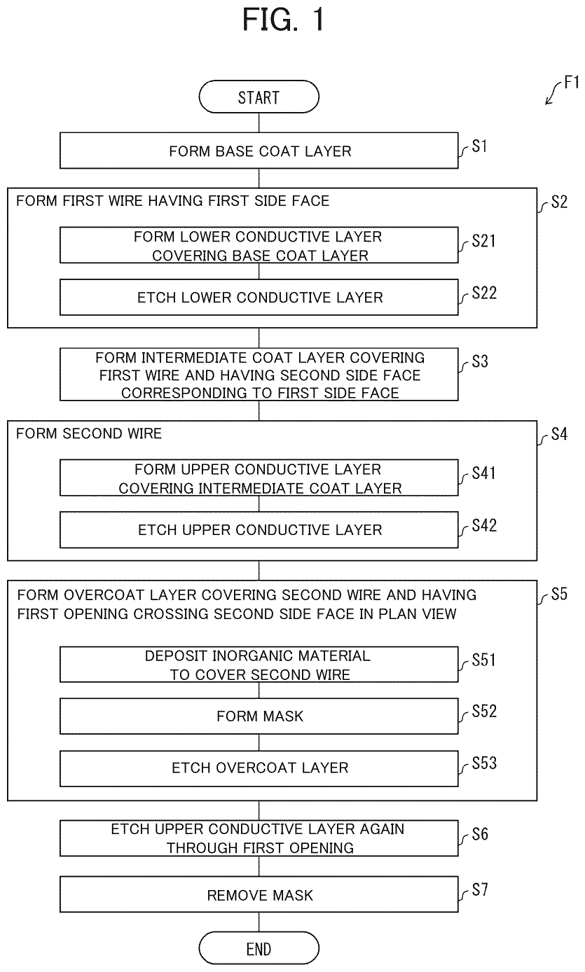

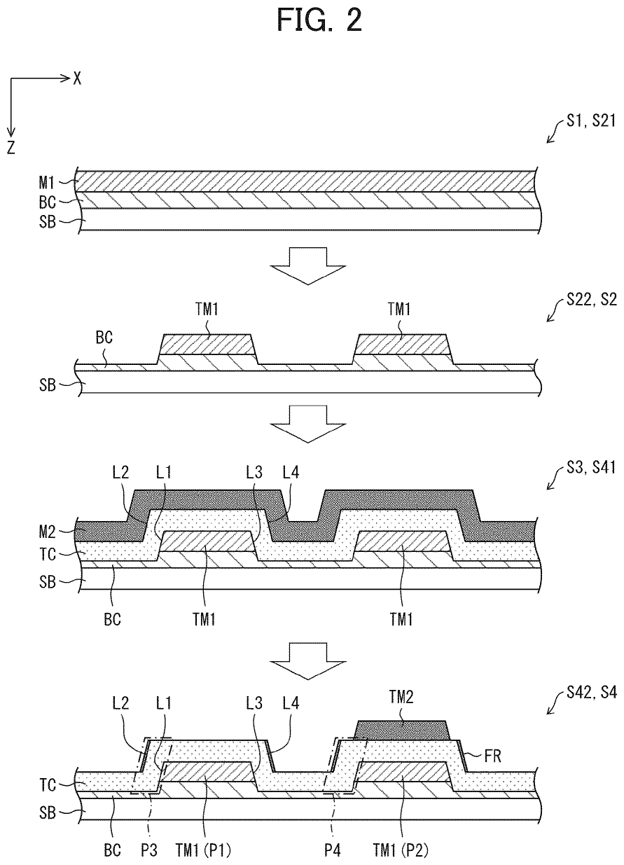

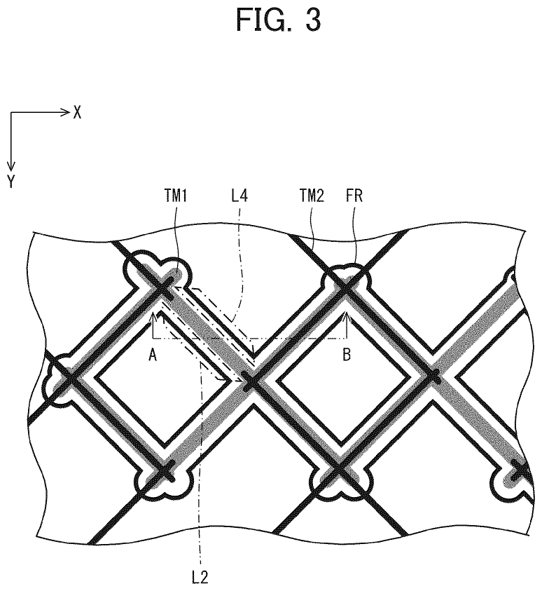

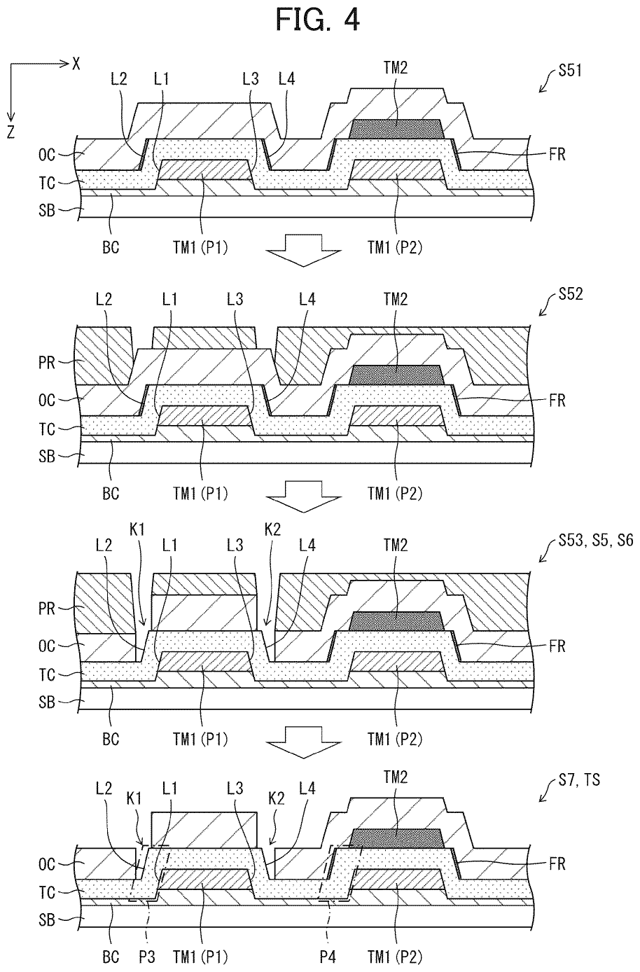

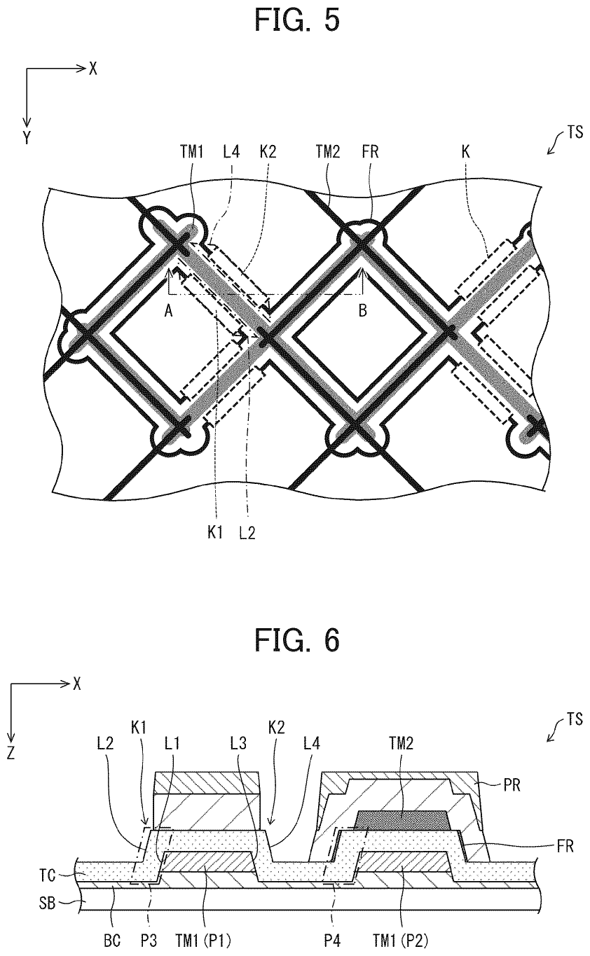

FIG. 1 is a flowchart showing an example of a method for manufacturing a touch sensor according to an embodiment of the present disclosure. FIG. 2 and FIG. 4 illustrate cross-sectional views showing an example of the method for manufacturing the touch sensor according to an embodiment of the present disclosure. FIG. 3 and FIG. 5 illustrate plan views showing an example of the method for manufacturing the touch sensor according to an embodiment of the present disclosure. Each of the lower-most cross-sectional views in FIG. 2 and FIG. 4 corresponds to a cross-sectional view taken from line A-B in FIG. 3 and FIG. 5.

In the present disclosure, the “plan view” is a plan view observed from a direction perpendicular to a substrate unless otherwise noted. The direction perpendicular to the substrate is a direction of the normal line of an upper face of the substrate; that is, a Z-direction in the drawings.

As shown in FIG. 1 and FIG. 2, in a method F1 for manufacturing a touch sensor, first, a base coat layer BC is formed on a substrate SB (Step S1). The substrate SB may be a circuit substrate, a display panel, or, simply, a support substrate. The base coat layer BC, which is an inorganic insulating film, may contain any one or more of, for example, silicon oxide, silicon nitride, and silicon oxynitride. The base coat layer BC may be formed by chemical vapor deposition (CVD).

Next, a lower conductive layer M1 is formed to cover the base coat layer BC (Step S21), and the lower conductive layer M1 is etched (Step S22). Hence, a first wire TM1 having a first side face L1 is formed above the substrate SB (Step S2). At Step S22, the lower conductive layer M1 may be dry-etched. Compared with wet-etching, dry-etching is anisotropic. Because of the anisotropy, dry-etching is suitable for microfabrication. At Step S22, the base coat layer BC may be etched. This is referred to as “over etching”.

Next, an intermediate coat layer TC is formed to cover the first wire TM1 (Step S3). The intermediate coat layer TC has a second side face L2 corresponding to the first side face L1. The intermediate coat layer TC, which is an inorganic insulating film, may contain one or more of, for example, silicon oxide, silicon nitride, and silicon oxynitride. The intermediate coat layer TC may be formed by chemical vapor deposition (CVD). The intermediate coat layer TC has projections and depressions in accordance with a structure of a layer below. For example, the second side face L2 of the intermediate coat layer TC inclines in association with the first side face L1 of the first wire TM1.

Subsequently, an upper conductive layer M2 is formed to cover the intermediate coat layer TC (Step S41). The upper conductive layer M2 is etched (Step S42) to form a second wire TM2 (Step S4). The second wire TM2 may partially overlap with the first wire TM1 in a plan view. Conversely, the first wire TM1 may include: a portion P1 not overlapping with the second wire TM2 in a plan view; and a portion P2 overlapping with the second wire TM2 in a plan view. Hereinafter, the non-overlapping portion P1 is referred to as a “first portion P1” and the overlapping portion P2 is referred to as a “second portion P2”.

The first side face L1 of the first wire TM1 may be a side face of the first portion P1 of the first wire TM1. The intermediate coat layer TC may include a portion P3 covering the first side face L1 of the first wire TM1. The intermediate coat layer TC may include a portion P4 covering a side face of the second portion P2 of the first wire TM1. Hereinafter, the portion P3 covering the first side face L1 is referred to as a “third portion P3”, and the portion P4 covering the side face of the second portion P2 is referred to as a “fourth portion P4”. The second side face L2 of the intermediate coat layer TC may be a surface of the third portion P3 across from the first wire TM1.

At Step S42, the upper conductive layer M2 may be dry-etched. As described before, dry-etching, which is anisotropic, is suitable for microfabrication. At Step S42, a portion of the upper conductive layer M2 might remain in a region other than a region in which the second wire TM2 is formed. Hereinafter, the portion of the upper conductive layer M2 remaining in a region other than the region in which the second wire TM2 is formed is referred to as a “remaining portion FR”. The remaining portion FR of the upper conductive layer M2 is likely to form in a region in which the surface of the intermediate coat layer TC is not substantially horizontal. For example, the remaining portion FR is likely to form on the second side face L2. The remaining portion FR of the upper conductive layer M2 is likely to form around the first wire TM1 in a plan view. Furthermore, the remaining portion FR of the upper conductive layer M2 is more likely to form as the surface of the intermediate coat layer TC inclines at a larger angle.

At Step S2, the first wire TM1 may be formed to have the third side face L3 across from the first side face L1. At Step S3, the intermediate coat layer TC may be formed to have the fourth side face LA corresponding to the third side face L3. The remaining portion FR of the upper conductive layer M2 is likely to form also on the fourth side face L4.

FIG. 3 shows an example in which the remaining portion FR of the upper conductive layer M2 is continuously formed on the side face of the intermediate coat layer TC corresponding to the side face of the first wire TM1. FIG. 3 illustrates the first wire TM1, the second wire TM2, and the remaining portion FR, but omits other constituent elements. In the example shown in FIG. 3, the remaining portion FR electrically connects two second wires TM2 formed separately. As a result, the two second wires TM2 are electrically short-circuited through the remaining portion FR.

Subsequently, as shown in FIG. 1 and FIG. 4, an overcoat layer OC is formed to cover the second wire TM2 (Step S5). The overcoat layer OC has a first opening K1 crossing the second side face L2 in a plan view. The first opening K1 may cross, in a plan view, the second side face L2 of the intermediate coat layer TC in a direction intersecting with a corresponding first wire TM1. The direction in which the first opening K1 crosses the second side face L2 may be a direction substantially perpendicular to the corresponding first wire TM1. The second side face L2 typically has an elongated shape whose longitudinal direction is substantially in parallel with a direction in which the first wire TM1 extends. Hence, the crossing direction of the first opening K1 may be a transverse direction of the second side face L2.

At Step S5, first, an inorganic material is deposited to cover the second wire TM2, so as to form a deposited layer formed of an inorganic insulating material and serving as the overcoat layer OC (Step S51). Then, on the overcoat layer OC, a mask PR is formed (Step S52). The mask PR may be formed of a liquid containing a photosensitive resin. The liquid is applied to form a coat, and the coat is exposed to light and developed by photolithography to form the mask PR. Then, the overcoat layer OC is etched (Step S53), so that the first opening K1 is formed. At Step S53, the overcoat layer OC may be dry-etched. Dry-etching is anisotropic and suitable for microfabrication. That is why overcoat layer OC is easily etched by dry-etching. The overcoat layer OC may be provided with an opening K (see, for example, FIG. 5) other than the first opening K1, as provided with the first opening K1.

At Step S5, furthermore, the overcoat layer OC may be formed to include a second opening K2 crossing the fourth side face L4 in a plan view. The second opening K2 may cross, in a plan view, the fourth side face LA of the intermediate coat layer TC in a direction intersecting with a corresponding first wire TM1. The direction in which the second opening K2 crosses the fourth side face LA may be a direction substantially perpendicular to the corresponding first wire TM1. The fourth side face L4 typically has an elongated shape whose longitudinal direction is substantially in parallel with a direction in which the first wire TM1 extends. Hence, the crossing direction of the second opening K2 may be a transverse direction of the fourth side face L4.

The first opening K1 may have an elongated shape extending substantially in parallel with the first side face LI in a plan view. The second opening K2 may have an elongated shape extending substantially in parallel with the third side face L3 in a plan view. Hence, the first opening K1 and the second opening K2 may have elongated shapes substantially in parallel with the corresponding first wire TM1 in a plan view.

The side face of the intermediate coat layer TC is separated from the corresponding side face of the first wire TM1 by a thickness of the intermediate coat layer TC in a cross-sectional view. Here, the “cross-sectional view” is a cross-sectional view taken along a section perpendicular to the first wire TM1 and to the substrate SB. Hence, the first opening K1 and the second opening K2 can be formed not to overlap with an upper face of the first wire TM1 in a plan view. Depending on a thickness of the first wire TM1, on a thickness of the intermediate coat layer TC, and on an inclination angle of the side face of the first wire TM1, the side face of the intermediate coat layer TC could be separated from the corresponding side face of the first wire TM1 in a plan view. In such a case, the first opening K1 and the second opening K2 can be formed not to overlap with the first wire TM1 in a plan view.

Following Step S5, the upper conductive layer M2 is etched again through the first opening K1 (Step S6). At Step S6, the upper conductive layer M2 may be etched again through an opening K other than the first opening K1. When the upper conductive layer M2 is etched again, the remaining portion FR on the upper conductive layer M2 can be removed. The etching at Step S6 may be carried out continuously or simultaneously with the etching at Step S53.

At Step S6, the upper conductive layer M2 may be dry-etched. The dry-etching at Step S52 and the dry-etching at Step S6 are beneficially carried out together at a single step.

At Step S6, the upper conductive layer M2 may be wet-etched. Compared with dry-etching, wet-etching is isotropic. Because of the isotropy, wet-etching is suitable for removing the upper conductive layer M2. Alternatively, at Step S6, the upper conductive layer M2 may be dry-etched and wet-etched. When etched twice, the upper conductive layer M2 can be removed without fail.

FIG. 5 shows an example in which the remaining portion FR of the upper conductive layer M2 is continuously formed on the side face of the intermediate coat layer TC corresponding to the side face of the first wire TM1, and, after that, removed through an opening. FIG. 5 illustrates the first wire TM1, the second wire TM2, the remaining portion FR, and an outline of an opening such as the first opening K1, but omits other constituent elements. In this example, the remaining portion FR is divided by the first opening K1 and another opening. As a result, the two second wires TM2 formed separately are electrically separated. Hence, the etching carried out again at Step S6 can reduce or eliminate electrical short circuit between electrodes of a touch sensor TS.

As the second side face L2 and the fourth side face L4 of the intermediate coat layer TC are inclined at larger angles, the remaining portion FR is more likely to form and the electrical short circuit is more likely to develop between the second wires TM2. The second side face L2 and the fourth side face LA are likely to be inclined at larger angles when the base coat layer BC is over-etched than when the base coat layer BC is not over-etched. Hence, as to the manufacturing method that involves over-etching of the base coat layer BC, it is more beneficial to carry out etching again at Step S6.

As illustrated in a lowermost cross-section of FIG. 4, following Step S6, the mask PR are delaminated and removed (Step S7). As described above, the touch sensor TS according to this embodiment includes: the substrate SB; the base coat layer BC positioned above the substrate SB; the first wire TM1 positioned above the substrate SB and having the first side face L1; the intermediate coat layer TC covering the first wire TM1 and having the second side face L2 corresponding to the first side face L1; the second wire TM2 positioned above the intermediate coat layer TC; and the overcoat layer OC covering the second wire TM2 and having the first opening K 1 crossing the second side face L2 in a plan view. Furthermore, the first wire TM1 may have the third side face L3 across from the first side face L1, the intermediate coat layer TC may have the fourth side face L4 corresponding to the third side face L3, and the overcoat layer OC may include the second opening K2 crossing the fourth side face L4 in a plan view.

As illustrated in FIG. 5, in the touch sensor TS, a conductive layer may be formed on the second side face L2 of the intermediate coat layer TC. This conductive layer may be the remaining portion FR of the upper conductive layer M2. More specifically, the conductive layer is not formed on the second side face L2 inside the first opening K1. The conductive layer may be formed on the second side face L2 outside the first opening K1. Furthermore, a conductive layer may be formed on the fourth side face L4. This conductive layer may be the remaining portion FR of the upper conductive layer M2. More specifically, the conductive layer is not formed on the fourth side face LA inside the second opening K2. The conductive layer may be formed on the fourth side face L4 outside the second opening K2. Moreover, a conductive layer may be formed on a side face of the fourth portion P4 of the intermediate coat layer TC. This conductive layer may be the remaining portion FR of the upper conductive layer M2.

### First Modification

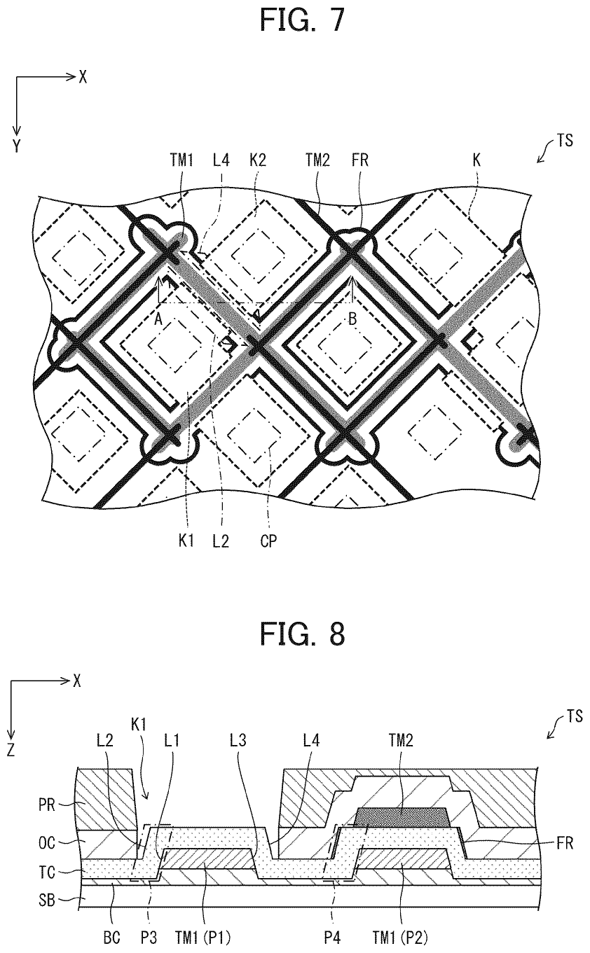

FIG. 6 and FIG. 7 illustrate a cross-sectional view and a plan view showing a modification of the method for manufacturing the touch sensor according to this embodiment.

FIG. 6 corresponds to a cross-sectional view taken along line A-B in FIG. 7. As illustrated in FIG. 6 and FIG. 7, at Step S5, an opening area of the first opening K1 may be increased. At Step S6, through the increased first opening K1, the upper conductive layer M2 may be etched again. For example, the first opening K1 may be formed to overlap with a center portion CP in a plan view. The center portion CP is in a region surrounded with at least one of the first wire TM1 or the second wire TM2. Here, the region surrounded with at least one of the first wire TM1 or the second wire TM2 includes: a region surrounded continuously; and a region surrounded intermittently. The region surrounded with at least one of the first wire TM1 or the second wire TM2 includes: a region surrounded only with the first wire TM1; a region surrounded only with the second wire TM2; and a region surrounded with both the first wire TM1 and the second wire.

The increased opening area can reduce absorption of light by the overcoat layer OC and improve light transmittance of the touch sensor TS. Likewise, an opening area of the opening K other than the first opening K1 may be increased.

### Second Modification

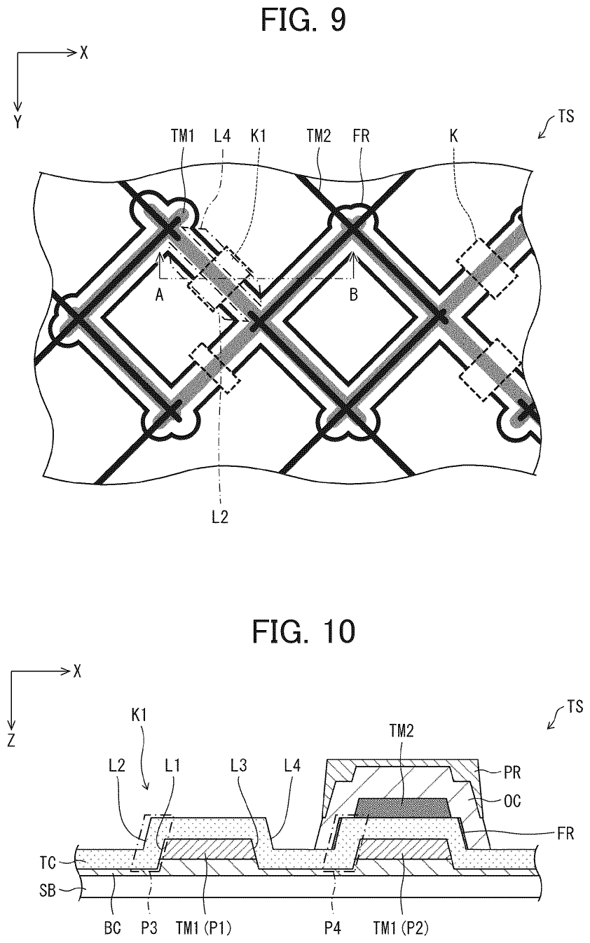

FIG. 8 and FIG. 9 illustrate a cross-sectional view and a plan view showing another modification of the method for manufacturing the touch sensor according to this embodiment.

FIG. 8 corresponds to a cross-sectional view taken along line A-B in FIG. 9. As illustrated in FIG. 8 and FIG. 9, the first opening K1 may be formed to cross, in a plan view, both the second side face L2 and the fourth side face L4 of the intermediate coat layer TC. In this modification, the first opening K1 crosses the first wire TM1 in a plan view. The first opening K1 may cross, in a plan view, both the second side face L2 and the fourth side face L4 of the intermediate coat layer TC in a direction intersecting with a corresponding first wire TM1. The direction in which the first opening K1 crosses the second side face L2 and the fourth side face LA may be a direction substantially perpendicular to the corresponding first wire TM1. The second side face L2 and the fourth side face LA typically have elongated shapes whose longitudinal direction is substantially in parallel with a direction in which the first wire TM1 extends. Hence, the crossing direction of the first opening K1 may be a transverse direction of the second side face L2 and the fourth side face L4.

### Third Modification

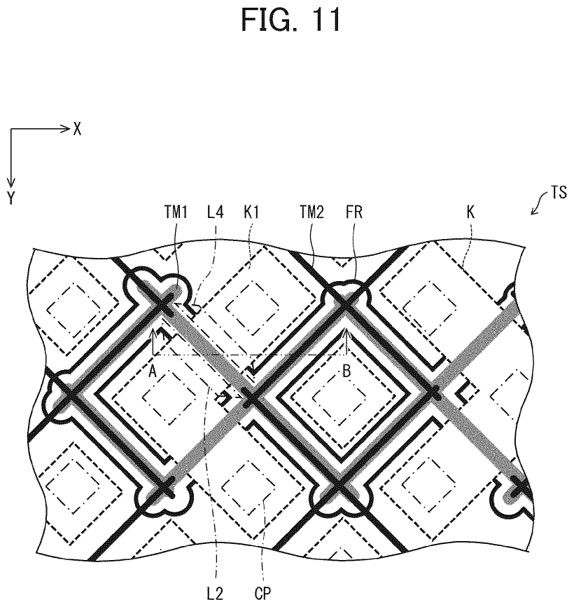

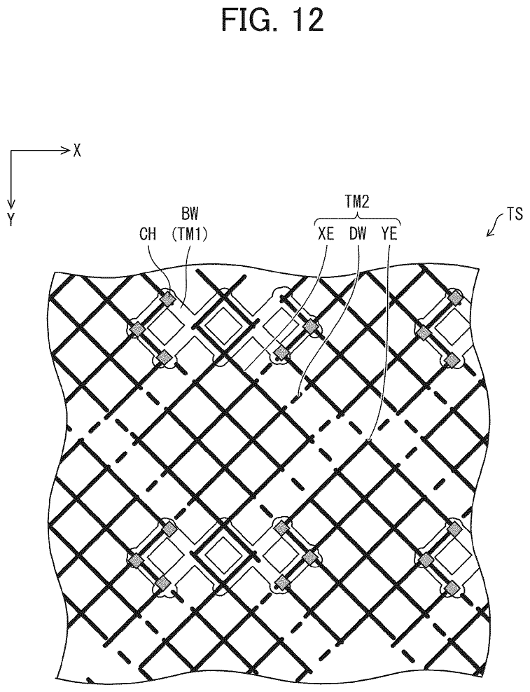

FIG. 10 and FIG. 11 illustrate a cross-sectional view and a plan view showing another modification of the method for manufacturing the touch sensor according to this embodiment.

FIG. 10 corresponds to a cross-sectional view taken along line A-B in FIG. 11. As illustrated in FIG. 10 and FIG. 11, the first opening K1 may be formed to overlap with: both the second side face L2 and the fourth side face L4 of the intermediate coat layer TC in a plan view; and the center portion CP in a plan view. The touch sensor TS according to the third modification is high in light transmittance as the touch sensor TS according to the first modification described before.

### First Configuration of Touch Sensor

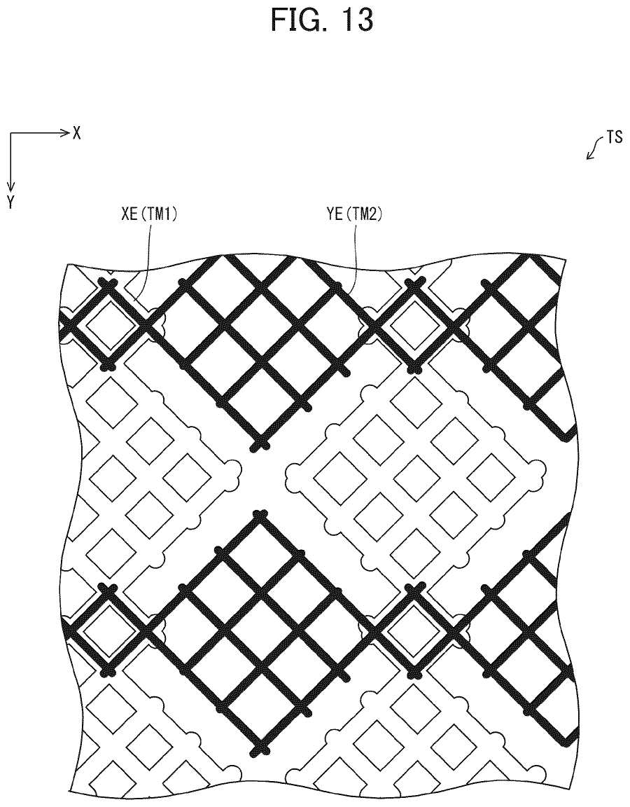

FIG. 12 is a plan view showing an example of a wiring pattern of a touch sensor according to an embodiment of the present disclosure. For the sake of simplicity, FIG. 12 omits the remaining portion FR of the upper conductive layer M2, and shows the first wire TM1, the second wire TM2, and contact holes CH alone. As shown in FIG. 12, the first wire TM1 may include a bridge wire BW. The second wire TM2 may include: an X electrode XE raised from, and intersected with, the bridge wire BW; and a plurality of Y electrodes YE electrically separated from the X electrode and electrically connected together through the bridge wire BW. The second wire TW2 may include a dummy wire DW positioned between the X electrode XE and the Y electrodes YE. The first wire TM1 and the second wire TM2 may be formed into a mesh.

The bridge wire BW and the Y electrodes YE are connected together with the contact holes CH. The X electrode XE extends in a Y-direction. A plurality of rows of X electrodes XE are provided in an X-direction. The Y electrodes YE adjacent to one another in the X-direction are connected together through the bridge wire BW. A plurality of rows of Y electrodes YE are provided in the Y-direction. A method F1 for manufacturing the touch sensor TS according to this embodiment can reduce or eliminate electrical short circuit between the X electrode and the Y electrodes YE arranged side by side.

### Second Configuration of Touch Sensor

FIG. 13 is a plan view showing another example of a wiring pattern of a touch sensor according to an embodiment of the present disclosure. For the sake of simplicity, FIG. 13 omits the remaining portion FR of the upper conductive layer M2, and shows the first wire TM1 and the second wire TM2 alone. As shown in FIG. 13, in the touch sensor TS according to this embodiment, the first wire TM1 may include the X electrode XE. The second wire TM2 may include the Y electrode YE electrically separated from the X electrode XE and raised from, and intersected with, the X electrode XE.

The X electrode XE extends in the Y-direction. A plurality of rows of X electrodes XE are provided in the X-direction. The Y electrode YE extends in the X-direction. A plurality of stages of Y electrodes YE are provided in the Y-direction. The method F1 for manufacturing the touch sensor TS according to this embodiment can reduce or eliminate electrical short circuit between the Y electrodes YE arranged side by side.

### Second Embodiment

Another embodiment of present disclosure will be described below. Note that, for convenience in description, like reference signs designate members having identical functions between this embodiment and the above embodiment. These members will not be elaborated upon repeatedly. Furthermore, for convenience in description, like reference signs designate steps that involves the same operations between this embodiment and the above embodiment. These steps will not be elaborated upon repeatedly.

### Method for Manufacturing Touch Sensor

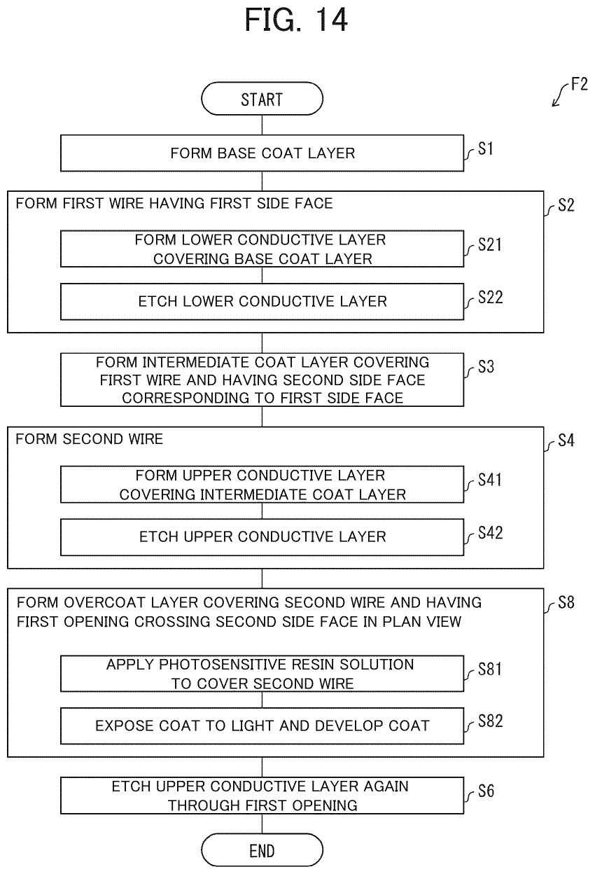

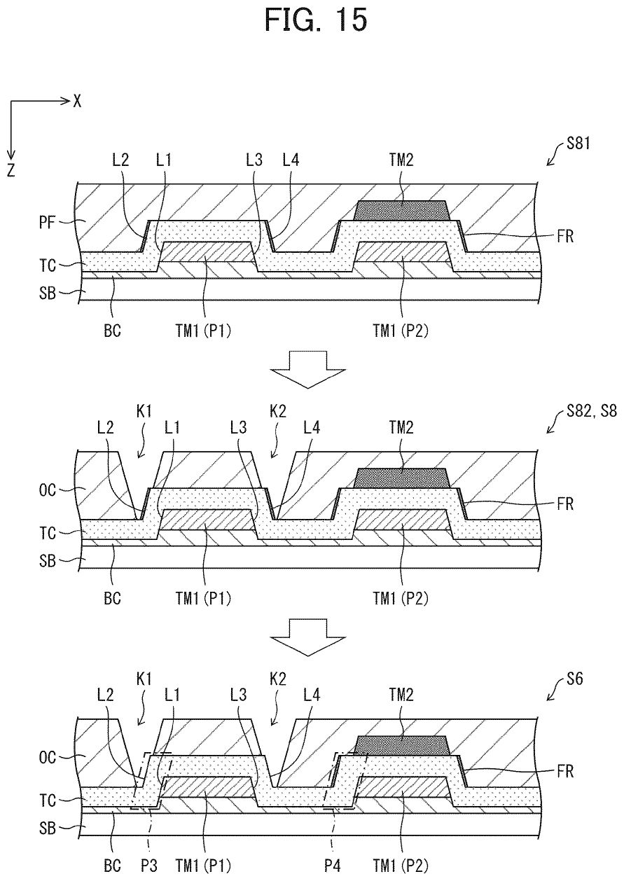

FIG. 14 is a flowchart showing an example of a method for manufacturing a touch sensor according to an embodiment of the present disclosure. FIG. 15 illustrates cross-sectional views showing an example of the method for manufacturing the touch sensor according to an embodiment of the present disclosure. As shown in FIG. 14, in a method F2 for manufacturing the touch sensor, Step S1 to Step S4 are sequentially carried out. Subsequently, the overcoat layer OC is formed to cover the second wire TM2 (Step S8). The overcoat layer OC has the first opening K1 crossing the second side face L2 in a plan view.

At Step S8, first, as illustrated in FIG. 15, a photosensitive resin solution is applied to cover the second wire TM2, so as to form a coat PF (Step S81). Then, the coat PF is exposed to light and developed, so as to form the overcoat layer OC having the first opening K1 (Step S82). The opening K other than the first opening K1 may be formed in the same manner as the first opening K1.

At Step S8 according to the second embodiment, the first opening K1 and the second opening K2 may be formed in the same manner as those formed at Step S5 according to the first embodiment described before. Following Step S8, Step S6 is carried out.

The method F2 for manufacturing the touch sensor according to this embodiment may omit Step S7. The method F2 for manufacturing the touch sensor according to this embodiment can be modified in various manners as the method F1 for manufacturing the touch sensor according to the embodiment described before.

### Third Embodiment

### Method for Manufacturing Display Device

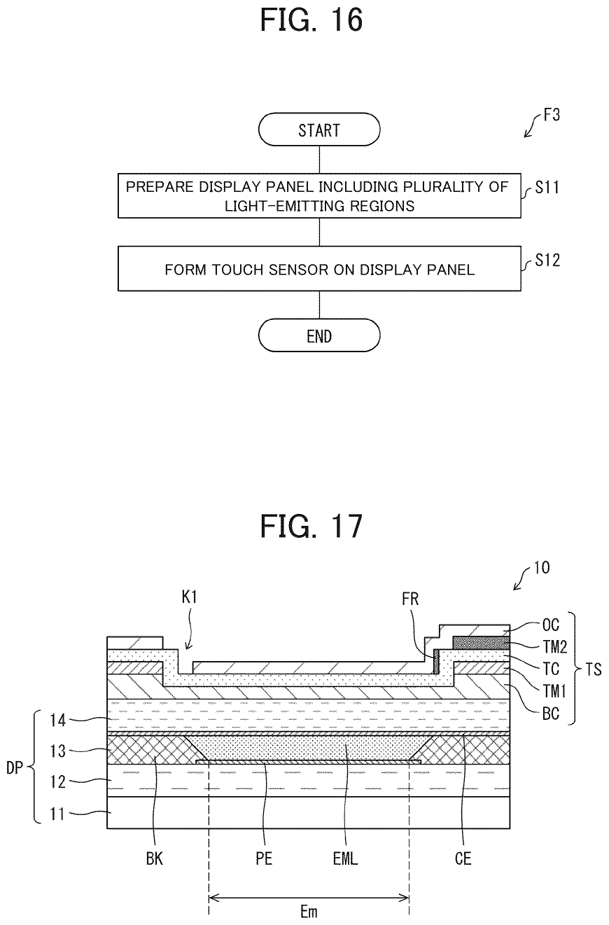

FIG. 16 is a flowchart showing an example of a method for manufacturing a display device according to an embodiment of the present disclosure. FIG. 17 is a cross-sectional view showing an example of the display device according to an embodiment of the present disclosure. As shown in FIG. 16 and FIG. 17, in a method F3 for manufacturing the display device, first, a display panel DP including a plurality of light-emitting regions is prepared to serve as the substrate SB (Step S11).

As an example, the display panel DP may include: a support substrate 11; a circuit layer 12 including a pixel circuit positioned above the support substrate 11; a light-emitting-element layer 13 including a light-emitting element positioned above the circuit layer 12; and a sealing layer 14 positioned above the light-emitting-element layer 13. The light-emitting element layer 13 includes: a pixel electrode PE; a bank BK covering an edge of the pixel electrode; a common electrode CE facing the pixel electrode PE; and a light-emitting layer EML positioned between the pixel electrode PE and the common electrode CE.

Subsequently, the touch sensor TS is formed on the display panel DP, using a method for manufacturing a touch sensor according to the present disclosure (Step S12). At Step S12, the base coat layer BC may be directly formed on the sealing layer 14. Step S12 may include either the method F1 for manufacturing the touch sensor according to the first embodiment as described before, or the method F2 for manufacturing the touch sensor according to the second embodiment as described before. Step S12 may include an improved or modified method F1 or method F2 for manufacturing the touch sensor according to the first embodiment or the second embodiment described before.

At Step S12, the touch sensor TS may be formed so that the first wire TM1 and the second wire TM2 may overlap, in a plan view, with spaces between the plurality of light-emitting regions Em. This arrangement can decrease a light-blocking rate of the first wire TM1 and the second wire TM2 that block light from the display panel DP, and reduce a fall in light luminance of a display device 10. The touch sensor TS may be formed so that the first opening K1 may overlap, in a plan view, with one or more of the plurality of light-emitting regions Em. This arrangement can decrease a light-absorbing rate of the overcoat layer OC that absorbs light from the display panel DP, and reduce a fall in light luminance of the display device 10. For example, as seen in the first modification or the third modification of the first embodiment described before, the opening area of the first opening K1 may be increased. Furthermore, the opening area of the opening K other than the first opening K1 may also be increased so that each opening may overlap with one or more of the light-emitting regions Em in a plan view.

As can be seen, the display device 10 according to this embodiment includes: the display panel DP; and the touch sensor TS according to the present disclosure. The touch sensor TS according to the present disclosure may include the touch sensor TS according to any one of the first to third embodiments described before, or may include a modified or improved touch sensor TS according to any one of the first to third embodiments described before.

The present disclosure shall not be limited to the embodiments described above, and can be modified in various manners within the scope of claims. The technical aspects disclosed in different embodiments are to be appropriately combined together to implement another embodiment. Such an embodiment shall be included within the technical scope of the present disclosure. Moreover, the technical aspects disclosed in each embodiment may be combined together to achieve a new technical feature.

1. A method for manufacturing a touch sensor, the method comprising:
a step of forming a first wire above a substrate, the first wire having a first side face;
a step of forming an intermediate coat layer covering the first wire and having a second side face corresponding to the first side face;
a step of forming a second wire, the second wire being formed of an upper conductive layer covering the intermediate coat layer, and the upper conductive layer being etched to form the second wire; and
a step of forming an overcoat layer covering the second wire and having a first opening crossing the second side face in a plan view observed from a direction perpendicular to the substrate; and
a step of etching the upper conductive layer again through the first opening.

2. The method for manufacturing the touch sensor according to claim 1,
wherein the first wire has a third side face across from the first side face, and the intermediate coat layer has a fourth side face corresponding to the third side face, and
the overcoat layer includes a second opening crossing the fourth side face in the plan view.

3. The method for manufacturing the touch sensor according to claim 2,
wherein the first opening and the second opening have elongated shapes substantially in parallel with the first wire in the plan view.

4. The method for manufacturing the touch sensor according to claim 2,
wherein neither the first opening nor the second opening overlaps with the first wire in the plan view.

5. The method for manufacturing the touch sensor according to claim 1,
wherein the first wire has a third side face across from the first side face, and the intermediate coat layer has a fourth side face corresponding to the third side face, and
the first opening crosses the fourth side face in the plan view.

6. The method for manufacturing the touch sensor according to claim 5,
wherein the first opening crosses the first wire in the plan view.

7. The method for manufacturing the touch sensor according to claim 1,
wherein the first wire includes: a first portion not overlapping with the second wire in the plan view; and a second portion overlapping with the second wire in the plan view, and
the first side face of the first wire is a side face of the first portion.

8. The method for manufacturing the touch sensor according to claim 1,
wherein the intermediate coat layer includes a third portion covering the first side face of the first wire, and
the second side face of the intermediate coat layer is a surface of the third portion across from the first wire.

9. The method for manufacturing the touch sensor according to claim 1,
wherein, at the step of forming the second wire, the upper conductive layer is dry-etched.

10. The method for manufacturing the touch sensor according to claim 1,
wherein, at the step of etching the upper conductive layer again, the upper conductive layer is dry-etched.

11. The method for manufacturing the touch sensor according to claim 1,
wherein, at the step of etching the upper conductive layer again, the upper conductive layer is wet-etched.

12. The method for manufacturing the touch sensor according to claim 1,
wherein, at the step of etching the upper conductive layer again, the upper conductive layer is dry-etched and wet-etched.

13. The method for manufacturing the touch sensor according to claim 1,
wherein, at the step of forming the overcoat layer, an inorganic insulating material is deposited to cover the second wire, and a deposited layer of the inorganic insulating material is etched so that the first opening is formed.

14. The method for manufacturing the touch sensor according to claim 1,
wherein, at the step of forming the overcoat layer, a photosensitive resin solution is applied to cover the second wire, and a coat of the photosensitive resin solution is exposed to light and developed to form the first opening.

15. The method for manufacturing the touch sensor according to claim 1, further comprising
a step of forming a base coat layer,
wherein a lower conductive layer is formed to cover the base coat layer, and the lower conductive layer is etched to form the first wire.

16. A method for manufacturing a display device, the method comprising:
a step of preparing a display panel including a plurality of light-emitting regions; and
a step of forming a touch sensor on the display panel, using the method for manufacturing the touch sensor according to claim 1.

17. (canceled)

18. (canceled)

19. A touch sensor, comprising:
a first wire positioned above a substrate and having a first side face;
an intermediate coat layer covering the first wire and having a second side face corresponding to the first side face;
a second wire positioned above the intermediate coat layer;
an overcoat layer covering the second wire and having a first opening crossing the second side face in a plan view observed from a direction perpendicular to the substrate; and
a conductive film formed on the second side face of the intermediate coat layer,
wherein the conductive film is not formed on the second side face inside the first opening and
the conductive film is formed on the second side face outside the first opening.

20. (canceled)

21. (canceled)

22. (canceled)

23. The touch sensor according to claim 19,
wherein the first wire includes a bridge wire, and
the second wire includes: an X electrode raised from, and intersected with, the bridge wire; and a plurality of Y electrodes electrically separated from the X electrode and electrically connected together through the bridge wire.

24. (canceled)

25. The touch sensor according to claim 19,
wherein the first wire includes an X electrode, and
the second wire includes a Y electrode electrically separated from the X electrode and raised from, and intersected with, the X electrode.

26. A display device, comprising:
a display panel; and the touch sensor according to claim 19.
